(19) United States
(12) Patent Application Publication
(10) Pub. No.: US 2009/0317562 A1
(43) Pub. Date: Dec. 24, 2009

(54) PROCESSING SYSTEM AND METHOD FOR PROCESSING A SUBSTRATE

(75) Inventors: Jose Manuel Dieguez-Campo, Hanau (DE); Michael Koenig, Frankfurt am Main (DE); Frank Stahr, Arnsdorf (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/244,527

(22) Filed: Oct. 2, 2008

Related U.S. Application Data
(60) Provisional application No. 61/074,418, filed on Jun. 20, 2008.

(51) Int. Cl. C23C 14/22; C23C 16/54; C23C 14/34; C23C 14/56

(52) U.S. Cl. 427/534; 118/729; 204/298.15; 204/192.1

(57) ABSTRACT

A processing system for processing a substrate includes a process chamber for receiving the substrate, a patterning device installed within the process chamber, and a mechanism for transferring the substrate into the process chamber and for aligning the substrate relative to the patterning device.

### CROSS-REFERENCES TO RELATED APPLICATIONS

This application is a nonprovisional of, and claims the benefit of the filing date of, U.S. Prov. Pat. Appl. No. 61/074,418, filed Jun. 20, 2008.

### BACKGROUND OF THE INVENTION

The present application relates to a processing system for processing a substrate comprising a process chamber for receiving said substrate in said processing chamber. The present application relates further to a method for processing a substrate comprising a step of providing a processing system as mentioned above.

In a number of technical applications, thin material layers are deposited on a substrate for generating a one-layer or multilayer system. For depositing the layers on a substrate, various methods may be used such as chemical vapor deposition (“CVD”), physical vapor deposition (“PVD”), evaporation, sputtering, etc.

A one-layer or multilayer electronic device, e.g. an organic light-emitting diode (“OLED”) device such as an OLED panel or screen, may be exposed to environmental influences. In order to protect the device against these influences, a protective element is provided on top of the layer and the layer system respectively. For example, a combination of a glass panel and a getter system for gettering humidity may be glued on top of the layer system.

Alternatively, for sealing the electronic device it is possible to deposit a protective layer stack on top of a functional layer and layer system respectively. the protective and/or barrier layer(s) may be deposited by use of a CVD deposition process. Sometimes, it may be required to form a structure or a pattern in the protective layer(s). Thus, shadow masks may be used for covering portions of the surface of the substrate during the coating process. A shadow mask is usually positioned and aligned relative to the substrate outside a coating chamber before the coating process, the substrate being positioned in a substrate carrier.

Because of the fact that a plurality of layers of different materials may have different patterns, a respective shadow mask may have to be removed after each deposition step and be replaced by another respective shadow mask. Manufacturing the protective layer stack may thus involve a lot of handling effort regarding the handling of the substrates, the shadow masks, and the substrate/mask carriers. Furthermore, handling of substrates is a source for the generation of particles, which may involve contamination of a layer and constrict the production of an effective protective layer stack.

### BRIEF SUMMARY OF THE INVENTION

It is an object of the present invention to provide a coating system and method for processing a substrate requiring less handling effort, particularly when producing a patterned sealing layer stack.

This object may be achieved by providing a processing system and a method for processing a substrate. The processing system for processing a substrate comprises a process chamber for receiving the substrate in the process chamber, a patterning device installed within the process chamber, and a mechanism for transferring the substrate into the process chamber and for aligning the substrate relative to the patterning device.

The processing system may be a coating system for depositing a protective layer or a protective layer stack, such as on top of an OLED layer or layer system. The coating process may be any conventional process, such as CVD, PVD, evaporation, sputtering, etc. The process chamber may comprise a coating chamber for the respective coating process.

The patterning device may be a shadow mask, such as for use in a CVD coating process. According to embodiments of the present invention, the patterning device is installed and fixedly arranged within the process chamber. Before processing, the substrate is arranged in a substrate carrier and transferred into the process chamber. A carrier or a plurality of carriers may be transported into a particular coating chamber. Afterwards, the carrier and/or the substrate are moved towards the shadow mask and aligned in front of the shadow mask. A lifting device may be used to lift the carrier and/or the substrate towards the shadow mask. The substrate may be aligned relative to the patterning device, such as through the use pins and corresponding receivers for the pins provided at the carrier and in the coating chamber respectively. In the coating chamber, a layer of a particular material having a particular pattern is deposited on the surface of the substrate(s).

After the deposition of a particular layer, the substrate is removed from the shadow mask, such as by lowering the substrate, and removed from the process chamber. At this stage, the shadow mask remaining located within the coating chamber is cleaned by a plasma treatment within the chamber before the next coating process is carried out in the chamber.

With embodiments of the invention, it is possible to provide a patterned/structured layer, such as by using a CVD coating method, wherein the shadow mask remains in the coating chamber after the layer has been deposited on the substrate. There is not need in such embodiments to adjust a shadow mask relative to a substrate attached to a carrier and attach the mask to the carrier outside a coating chamber. Therefore, contamination of the protective layer stack by particles released from the mask during a handling step may be avoided.

In the meantime, the shadow mask remains within the coating chamber in a vacuum atmosphere after the particular coating step has been terminated. It is possible to clean the mask, such as by providing plasma in the vicinity of the patterning device, before processing another substrate. The cleaning process may be carried out as soon as the substrates have been removed from the coating chamber, such as into a lock chamber that may be evacuated and/or vented while cleaning the mask.

According to embodiments of the invention, the effectiveness of the system, such as measured by the cycle time/uptime of the system, may be improved. Furthermore, because of plasma cleaning of the mask between two coating steps, the quality of the pattern and the purity and perfection of the layer stack may be improved.

In one embodiment of the invention, the processing system comprises a plasma source for providing a plasma in the vicinity of the patterning device for cleaning the patterning device. The plasma source may be arranged within the process chamber. The plasma cleaning step is usually carried out between two processing/coating steps.

Particularly, the mechanism is configured to move the substrate relative to the patterning device at least from a transfer position into a processing position. A relative movement comprises moving the substrate and/or the patterning device to align the substrate relative to the patterning device. The transfer position may be a position inside or outside the process chamber. The processing position is a position inside the process chamber where the substrate is usually positioned close to the shadow mask for depositing a patterned layer on the surface of a substrate.

The mechanism may, in some embodiments, comprise at least a handling system for moving the substrate relative to the patterning device in the process chamber and to transfer the substrate from the transfer position into the processing position. Merely by way of example, the handling system may comprise a robot arm having a mechanism for engaging a corresponding mechanism provided at the substrate carriers for receiving, releasing, lifting, and/or lowering the substrate carrier and/or the substrate. The invention is not limited to a particular handling and/or transport system, but maybe implemented with any handling and/or transport system that provides a movement of a substrate from the transfer position into the processing position.

In one embodiment, the processing system comprises at least a substrate carrier for carrying at least a substrate. The substrate may be attached to a substrate carrier, particularly when it is outside the process chamber.

Particularly, the substrate carrier and/or the process chamber comprise the mechanism for aligning the substrate relative to the patterning device. Such a mechanism for aligning may comprise a guidance, pins and corresponding cavities for receiving the pins, etc.

In another embodiment of the invention, the mechanism for transferring the substrate comprises a mechanism for lifting and/or lowering the substrate. Such a mechanism for lifting and/or lowering the substrate may be provided in the form of a handling arm. For example, the mechanism may comprise a device for actuating lifting pins provided in the substrate carrier for lifting and/or lowering a substrate carrier and/or the substrate.

In another embodiment of the invention, the processing system may comprise a lock chamber coupled to the process chamber.

Methods for processing a substrate according to embodiments of the invention comprise (a) providing a processing system as described above; (b) transferring a substrate into the process chamber; (c) moving the substrate relative to the patterning device from a transfer position into a coating position; (d) processing the substrate; (e) removing the substrate from the process chamber; and (f) providing plasma cleaning of the patterning device arranged in the process chamber. Step (e) is usually carried out while the coated substrate is locked out of the coating system via a lock chamber and/or while a new substrate to be coated is locked in the coating system via a lock chamber. Therefore, time used for evacuating and venting the lock chamber may be used for plasma cleaning the mask.

In one embodiment, step (c) includes aligning the substrate relative to the patterning device.

In some embodiments, step (c) includes moving/lifting the substrate towards the patterning device to arrange the substrate in the vicinity of the patterning device in the coating position. the mask may be fixedly arranged within the chamber or it may be moveably arranged within the chamber. Either the substrate or the mask, or both the substrate and the mask, may be moved such that the substrate is finally in the processing position relative to the mask.

Particularly, step (e) may include moving the substrate away and/or lowering the substrate from the patterning device and/or transferring the substrate out of the process chamber.

Methods according to the invention may comprise repeating steps (b) to (e) to process another substrate. The may, in particular, comprise repeating steps (b) to (f) to process another substrate and clean the mask after every coating process in a cycle of n=0, 1, 2, 3, . . . repetitions of steps (b) to (f).

The features described above are meant to be protected by themselves or in any combination with the described device and/or method features.

### BRIEF DESCRIPTION OF THE DRAWING

Further objects and advantages result from the following description of specific embodiments.

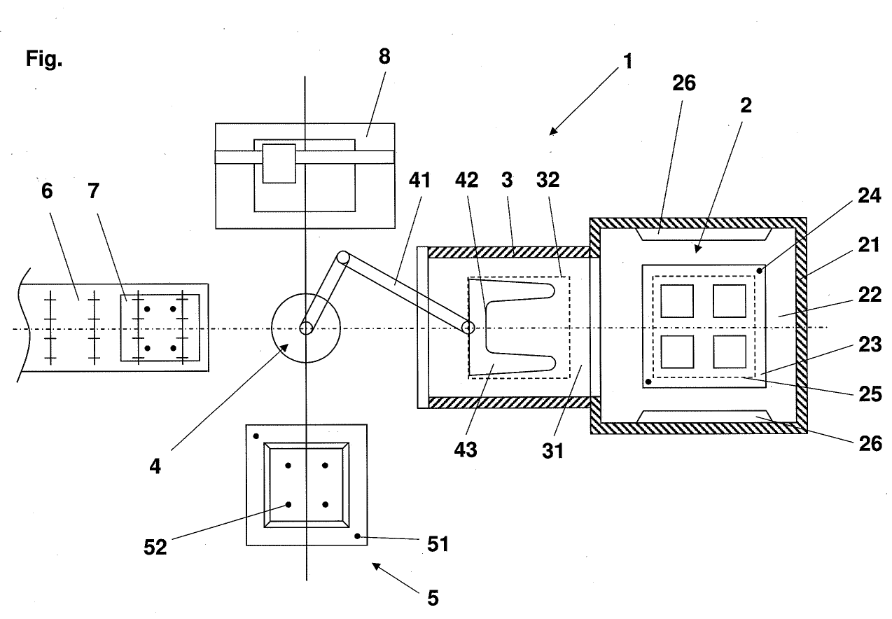

The drawing in FIG. 1 shows a schematic top view of an embodiment of a coating system according to the invention.

### DETAILED DESCRIPTION OF THE INVENTION

The drawing illustrates an embodiment of a coating system 1 according to the invention.

The coating system 1 comprises a vacuum coating chamber 2 (recipient), a lock chamber 3 coupled to the vacuum coating chamber 2, and a handling robot 4 for handling substrate carriers 5. Further more, the coating system 1 may comprise a transport or conveyer system 6 for delivering substrates 7 to the coating system 1 and/or coated substrates 7 away from the coating system 1. Moreover, the coating system 1 may comprise an inkjet printer 8 for printing a pattern, such as of a polymer material, on the surface of a substrate 7.

The vacuum coating chamber 2 comprises a housing 21 defining an inner space 22 of the vacuum coating chamber 2. In the inner space 22 of the vacuum coating chamber 2 a shadow mask 23 is fixedly installed. Furthermore, the vacuum coating chamber 2 comprises coating tools (not shown), such as for providing a CVD coating process in the inner space 22 of the vacuum coating chamber 2.

The shadow mask 23 has pin holes 24 for receiving adjustment pins 51 provided at a substrate carrier 5 for adjusting a substrate 7 attached to a carrier 5 relative to the mask 23 in a coating position indicated by dashed lines 25. According to embodiments of the invention, a coating system 1 comprises a plasma source 26 that is arranged in the inner space 22 of the coating chamber 2. While there is no substrate in the inner space 22 of the coating chamber 2, a plasma is generated in the vicinity of the shadow mask 23 for providing a cleaning process to clean the shadow mask 23 by use of a plasma chemical process. Particles removed from the mask 23 during the cleaning process are removed from inner space 22 of the coating chamber 2 before carrying out another coating process. The particles removed from the mask 23 in the cleaning process are gaseous reaction products, which may be removed from the inner space 22 of the coating chamber 2 by a vacuum pump system (not shown).

The lock chamber 3 is coupled with the coating chamber 2 via gate valves 31. The lock chamber 3 provides for transferring substrates from an atmospheric pressure outside the lock chamber 3 into a vacuum atmosphere provided in the inner space 22 of the coating chamber 2 and vice versa. In dashed lines, a transfer position 32 is indicated in which a substrate is held during an evacuation and/or venting process of the lock chamber 3.

The handling robot 4 comprises a drive (not shown) for driving a robot arm 41 that is connected with a support element 42 for supporting a substrate carrier 5 and/or a substrate 7. The support element 42 has a lifting mechanism 43 for interacting with lifting pins 52 provided at the substrate carrier 5 in order to lift the carrier 5 (and thus the substrate 7 attached to the carrier 5) into the coating position 25 arranged in the inner space 22 of the coating chamber 2.

Before the substrate carrier 5 is transported into the lock chamber by the handling robot 4, a substrate 7 received from the transport conveyer 6 is attached to the substrate carrier 5. As mentioned above, the substrate carrier 5 comprises adjustment pins 51 for engagement with corresponding pin holes 24 provided at the mask 23, and lifting pins 52 for interacting with a lifting mechanism 43 provided at the handling robot 4 for lifting a substrate from a transfer position into the coating position 25.

According to embodiments of the invention, the shadow mask 23 remains in the inner space 22 of the coating chamber 2 during a number of coating cycles. Between the coating steps, the mask 23 may be cleaned by a plasma cleaning system 26 that is also provided within the inner space 22 of the vacuum coating chamber 2.

Therefore, it may be unnecessary to fix a mask to the carrier before starting the coating process, and thereby also to remove the mask from the carrier after terminating the coating process, thus avoiding handling steps and contamination of the substrate attached to the substrate carrier by particles released from the mask.

Having fully described several embodiments of the present invention, many other equivalent or alternative processing systems and methods of the present invention will be apparent to those of skill in the art. These alternatives and equivalents are intended to be included within the scope of the invention, as defined by the following claims.

What is claimed is:

1. A processing system for processing a substrate comprising:
a process chamber for receiving the substrate in the process chamber;
a patterning device installed within the process chamber; and
a mechanism for transferring the substrate into the process chamber and for aligning the substrate relative to the patterning device.

2. The processing system according to claim 1 further comprising a plasma source for providing a plasma in a vicinity of the patterning device for cleaning the patterning device.

3. The processing system according to claim 1 wherein the mechanism for transferring the substrate into the process chamber and for aligning the substrate relative to the patterning device is configured to move the substrate relative to the patterning device at least from a transfer position into a processing position.

4. The processing system according to claim 3 wherein the mechanism for transferring the substrate into the process chamber and for aligning the substrate relative to the patterning device comprises at least a handling system.

5. The processing system according to claim 4 wherein the handling system comprises means for receiving, releasing, lifting, and/or lowering a substrate.

6. The processing system according to claim 1 further comprising at least a substrate carrier for carrying at least a substrate.

7. The processing system according to claim 6 wherein the substrate carrier and/or the process chamber comprises a mechanism for aligning the substrate relative to the patterning device.

8. The processing system according to claim 1 wherein the mechanism for transferring the substrate comprises means for lifting and/or lowering the substrate.

9. The processing system according to claim 1 further comprising a lock chamber coupled with the process chamber.

10. A method for processing a substrate comprising:
a) providing a processing system comprising:
a process chamber for receiving the substrate;
a patterning device installed within the process chamber; and
a mechanism for transferring the substrate into the process chamber and for aligning the substrate relative to the patterning device;
b) transferring the substrate into the process chamber;
c) moving the substrate relative to the patterning device from a transfer position into a coating position;
d) processing the substrate;
e) removing the substrate from the process chamber; and
f) providing plasma cleaning of the patterning device arranged in the process chamber.

11. The method according to claim 10 wherein step c) includes aligning the substrate relative to the patterning device.

12. The method according to claim 10 wherein step c) includes moving/lifting the substrate towards the patterning device to arrange the substrate in a vicinity of the patterning device in the coating position.

13. The method according to claim 10 wherein step e) includes:
moving the substrate away and/or lowering the substrate from the patterning device; and
transferring the substrate out of the process chamber.

14. The method according to claim 10 further comprising repeating steps
b) to f) to process another substrate.
